(19) United States
(12) Patent Application Publication
(10) Pub. No.: US 2025/0167473 A1
(43) Pub. Date: May 22, 2025

(54) Server System Low Profile Connector System

(71) Applicant: Dell Products L.P., Round Rock, TX (US)

(72) Inventors: James Utz, Georgetown, TX (US); Sanjiv Sinha, Austin, TX (US); Shih-Pin Tseng, Taipei (TW)

(73) Assignee: Dell Products L.P., Round Rock, TX (US)

(21) Appl. No.: 18/514,502

(22) Filed: Nov. 20, 2023

(51) Int. Cl. H01R 12/72; H01R 12/52; H01R 12/71

(52) U.S. Cl. CPC H01R 12/721; H01R 12/52; H01R 12/716

(57) ABSTRACT

A low profile connector system. The low profile connector system includes a printed circuit board and a low profile connector mounted on the printed circuit board, the low profile connector including: a connector housing, the connector housing defining a card insertion portion, the card insertion portion being positioned along an edge of the printed circuit board; a connector datum contained within the connector housing, the connector datum extending from one interior side of the connector housing to another interior side of the connector housing; and wherein the connector housing is mounted to the printed circuit board at a specifically configured connector mounting portion to allow insertion of a double sided peripheral card into the card insertion portion.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing low profile connector system that provides a single sided card optimized low profile connector and a low profile optimized double sided peripheral card.

In one embodiment, the invention relates to a low profile connector, comprising: a connector housing, the connector housing defining a card insertion portion, the card insertion portion being positioned along an edge of a printed circuit board; a connector datum contained within the connector housing, the connector datum extending from one interior side of the connector housing to another interior side of the connector housing; and wherein the connector housing is mounted to the printed circuit board at a specifically configured connector mounting position to allow insertion of a double sided peripheral card into the card insertion portion.

In another embodiment, the invention relates to a low profile connector system comprising: a printed circuit board and a low profile connector mounted on the printed circuit board, the low profile connector comprising: a connector housing, the connector housing defining a card insertion portion, the card insertion portion being positioned along an edge of a printed circuit board; a connector datum contained within the connector housing, the connector datum extending from one interior side of the connector housing to another interior side of the connector housing; and wherein the connector housing is mounted to the printed circuit board at a specifically configured connector mounting position to allow insertion of a double sided peripheral card into the card insertion portion.

In another embodiment, the invention relates to a system comprising: a processor; a data bus coupled to the processor; and, a low profile connector system, the low profile connector system comprising low profile connector system comprising: a printed circuit board; and, a low profile connector mounted on the printed circuit board, the low profile connector comprising: a connector housing, the connector housing defining a card insertion portion, the card insertion portion being positioned along an edge of the printed circuit board; a connector datum contained within the connector housing, the connector datum extending from one interior side of the connector housing to another interior side of the connector housing; and wherein the connector housing is mounted to the printed circuit board at a specifically configured connector mounting portion to allow insertion of a double sided peripheral card into the card insertion portion.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A and 4B, generally referred to as FIG. 4, respectively show top and side views of a server system low profile connector system.

FIG. 5 shows a side view of a portion of a low profile connector system.

FIG. 6 shows a top view of a low profile connector.

FIGS. 7A and 7B, generally referred to as FIG. 7, respectively show top views of typical and modified lead portions of a low profile connector.

FIGS. 8A and 8B, generally referred to as FIG. 8, respectively show top views of typical and modified pad portions of a low profile connector.

### DETAILED DESCRIPTION

Various aspects of the disclosure include an appreciation that it is known to provide information handling systems with connector systems which conform to low profile specifications such as the PCI Express M.2 specification. Various aspects of the present disclosure include an appreciation that the PCI Express M.2 specification (formerly known as the Next Generation Form Factor (NGFF)) is a specification for internally mounted computer expansion cards and associated connectors. Various aspects of the present disclosure include an appreciation that cards conforming to a low profile specification such as the PCI Express M.2 specification often conform to standard form factors defined by the low profile specification.

Various aspects of the present disclosure include an appreciation that connectors conforming to a low profile specification such as the PCI Express M.2 specification, are designed to mate with single sided cards to conform to the low profile specification. Specifically, H2.15-2.3 mm M.2 connectors are designed for use and designated as single-sided M.2 connectors per the PCI Express M.2 Specification. When used on printed circuit boards, these low-profile connectors typically do not allow for use with peripheral cards having a second side of components. Various aspects of the present disclosure include an appreciation that prior solutions enabling double sided peripheral cards with low-profile M.2s connector use midplane mount type M.2 connectors. Various aspects of the present disclosure include an appreciation that midplane mount type M.2 connectors often require a PCB cutout and extra width of their PCB for side supports. Various aspects of the present disclosure include an appreciation that low profile connectors can include insertion keys which mate with keying notches located on peripheral cards designed to mate with particular low profile connectors.

A system and method are disclosed for providing low profile connector system that provides a single sided card optimized low profile connector and a low profile optimized double sided peripheral card.

In certain embodiments, the low profile connector system uses a single sided low profile connector. In certain embodiments, the single sided low profile connector comprises a top mount connector. In certain embodiments, the single sided low profile connector comprises a single sided M.2 top mount connector. In certain embodiments, such a low profile connector system allows for a narrower peripheral card printed circuit board. In certain embodiments, such a low profile connector system consumes less depth within the information handling system.

In certain embodiments, the low profile connector system can be used for double sided peripheral devices, when the double sided devices are placed very aggressively near the edge of a printed circuit board (often referred to as an interposer board) on which a low profile connector is mounted. In certain embodiments, the low profile connector system can be used for double sided peripheral devices which conform to a double sided portion of the PCIe M.2 specification. Using this unique application, these connectors can shrink the interposer printed circuit board size and allows for heat extraction from both sides of a peripheral device such as a M.2 Storage Module. Various aspects of the disclosure include an appreciation that bottom side heat extraction has typically been restricted by the underlying interposer printed circuit board in known information handling system designs. Such a low profile connector system advantageously uses an industry standard M.2 connector in a manner which is not prescribed or expected by the PCIe M.2 Specification.

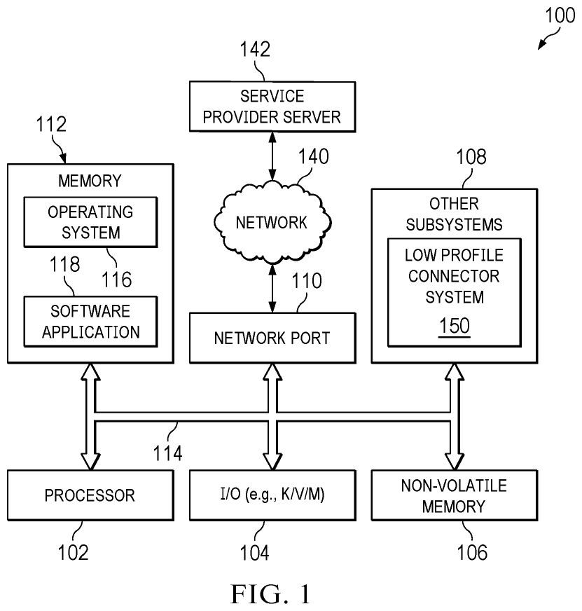

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include low profile connector system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100. In certain embodiments, the server type information handling system comprises a blade server type information handling system. As used herein, a blade server type information handling system broadly refers to an information handling system which is physically configured to be mounted within a server rack.

In certain embodiments, the low profile connector system 150 includes a single sided card optimized low profile connector and a low profile optimized double sided peripheral card. In certain embodiments, the low profile connector system 1450 uses a single sided low profile connector. In certain embodiments, the single sided low profile connector comprises a top mount connector. In certain embodiments, the single sided low profile connector comprises a single sided M.2 top mount connector. In certain embodiments, such a low profile connector system 150 allows for a narrower peripheral card printed circuit board. In certain embodiments, such a low profile connector system 150 consumes less depth within the information handling system.

In certain embodiments, the low profile connector system 150 can be used for double sided peripheral devices, when the double sided devices are placed very aggressively near the edge of a printed circuit board on which a low profile connector is mounted. In certain embodiments, the low profile connector system 150 can be used for double sided peripheral devices which conform to a double sided portion of the PCIe M.2 specification. Using this unique application, these connectors can shrink the interposer printed circuit board size and allows for heat extraction from both sides of a peripheral device such as a M.2 storage module. Various aspects of the disclosure include an appreciation that bottom side heat extraction has typically been restricted by the underlying interposer printed circuit board in known information handling system designs. Such a low profile connector system advantageously uses an industry standard M.2 connector in a manner which is not prescribed or expected by the PCIe M.2 Specification.

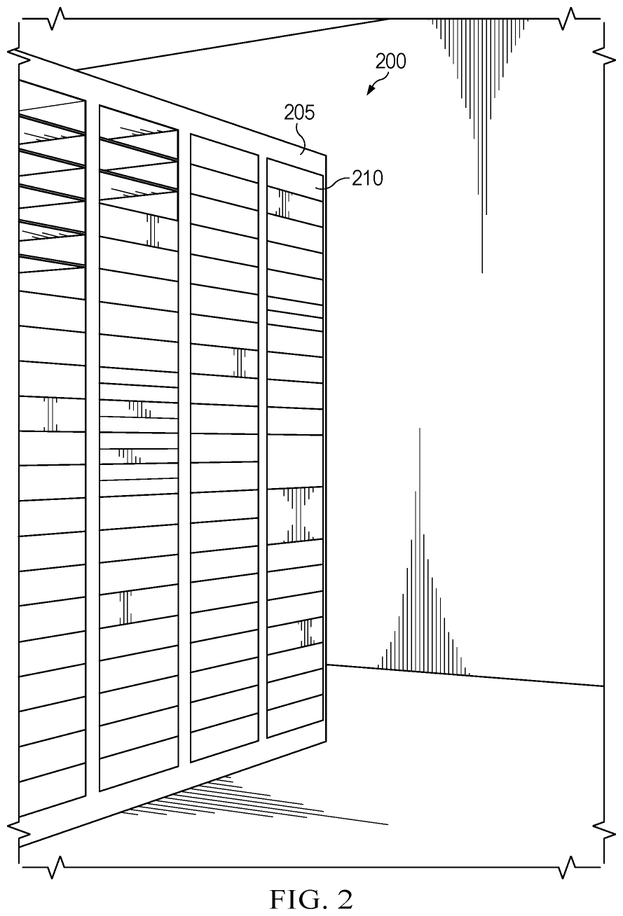

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high and a 4U rack height is substantially (i.e., +/−20%) 7.0″ high.

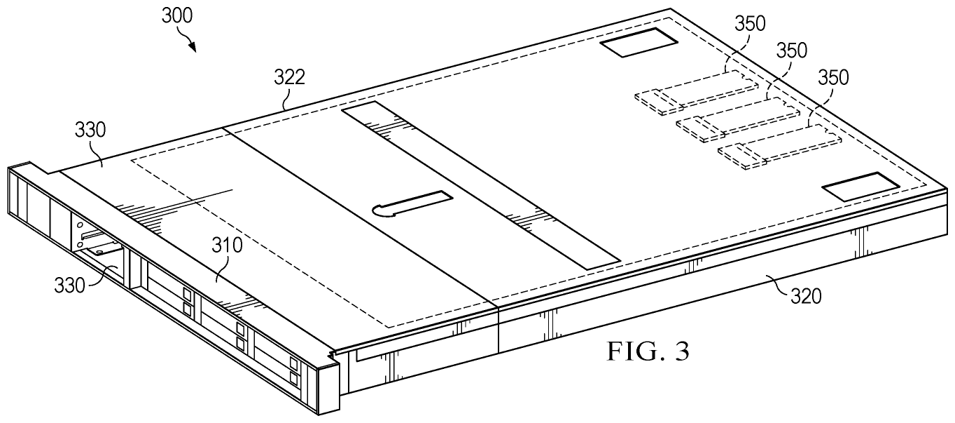

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300. In certain embodiments, the blade type information handing system 300 includes a bay 330 via which components may be mounted to the blade type information handling system. In certain embodiments, the blade type information handling system 300 includes one or more low profile connector systems 350. In certain embodiments, each low profile connector system 350 conforms to low profile connector system 150.

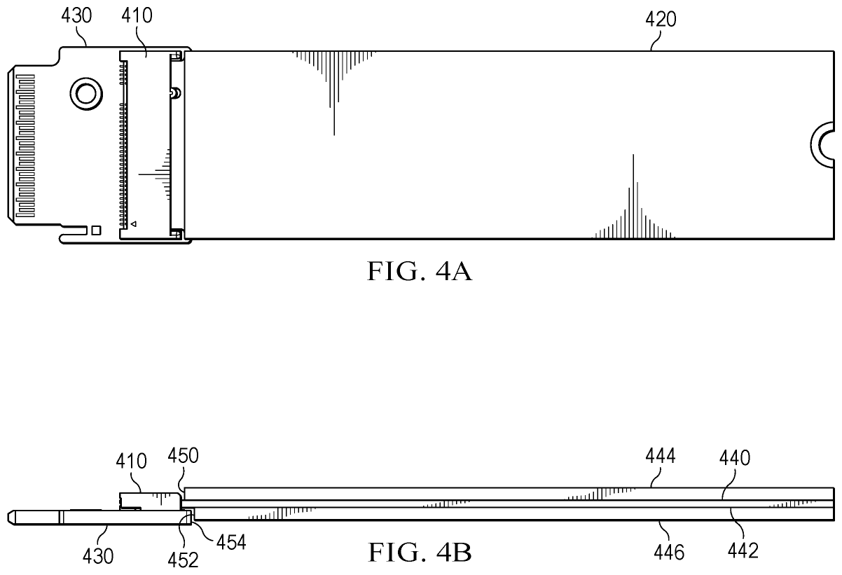

FIGS. 4A and 4B, generally referred to as FIG. 4, respectively show top and side views of a single sided card optimized low profile connector 410 and a low profile optimized double sided peripheral card 420 of a server system low profile connector system 400. In certain embodiments, the low profile connector 410 is attached to a printed circuit board 430. In certain embodiments, the printed circuit board comprises an interposer board, a planar board, or a combination thereof. In certain embodiments, the server system low profile connector system 400 conforms to the low profile connector system 150.

In certain embodiments, the printed circuit board 430 includes a modified connector pad footprint and a highly-aggressive electrical layout to achieve placement of low profile, single sided card optimized connector very close to the an edge of the printed circuit board thereby allowing a double-sided module to be installed.

In certain embodiments, the low profile connector system 400 uses a single sided low profile connector 410. In certain embodiments, the single sided low profile connector 410 comprises a top mount connector. In certain embodiments, the single sided low profile connector comprises a single sided M.2 top mount connector. In certain embodiments, such a low profile connector system 400 allows for a narrower peripheral card printed circuit board (e.g., low profile optimized double sided peripheral card 420). In certain embodiments, such a low profile connector system 400 consumes less depth within an information handling system.

In certain embodiments, the low profile connector system 400 can be used for double sided peripheral devices, when the double sided devices are placed very aggressively near the edge of a printed circuit board on which a low profile connector is mounted. In certain embodiments, the doubled sided peripheral device includes components mounted to a top side 440 and components mounted to a bottom side 442. For illustration purposes the components mounted to the top side are represented by box 444 and the components mounted to the bottom side are represented by box 446. In certain embodiments, components mounted to the top side are positioned closer to the connector 410 (see e.g., edge 450 of box 444) and components mounted to the top side are set back (see e.g., edge 452) relative to the mounting area for components mounted to the top side so as to fit next to an edge 454 of the printed circuit board 430.

In certain embodiments, the low profile connector system 400 can be used for double sided peripheral devices which conform to a double sided portion of the PCIe M.2 specification. Using this unique application, these connectors can shrink the interposer printed circuit board size and allow for heat extraction from both sides of a peripheral device such as a M.2 storage module. Various aspects of the disclosure include an appreciation that bottom side heat extraction has typically been restricted by the underlying interposer printed circuit board in known information handling system designs. Such a low profile connector system advantageously uses an industry standard M.2 connector in a manner which is not prescribed or expected by the PCIe M.2 Specification.

As used herein, a low profile, single sided card optimized connector broadly refers to a connector which conforms to a low profile specification which can be used to connect with a double sided peripheral device. In certain embodiments, the low profile specification corresponds to the PCIe M.2 specification. As used herein, a double sided peripheral device broadly refers to a peripheral device which conforms to a low profile specification which can be configured to mount components on a top side and a bottom side of a peripheral card. In certain embodiments, the low profile specification corresponds to the PCIe M.2 specification.

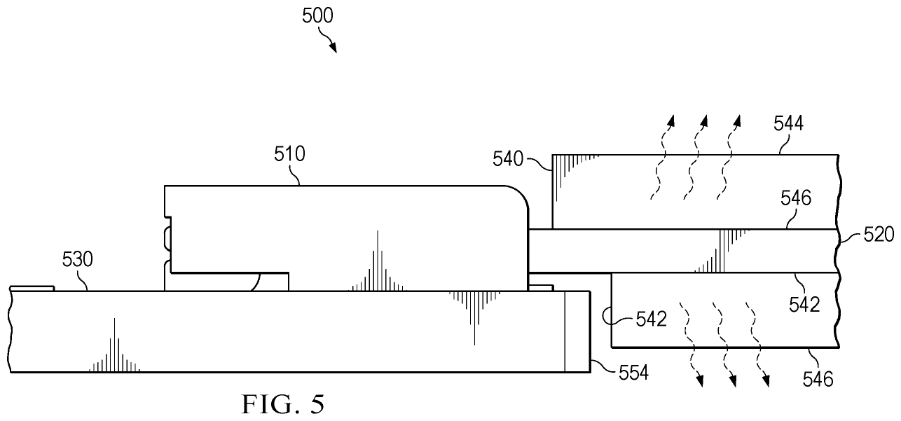

FIG. 5 shows a side view of a portion 500 of a low profile connector system. In certain embodiments, the low profile connector system conforms to low profile connector system 150.

The low profile connector system includes a low profile connector 510, a peripheral card 520 and a board 530 to which the low profile connector 510 is mounted. In certain embodiments, the peripheral card 520 is a double sided peripheral card with a first side 540 and a second side 542 (also referred to as a double sided module). For illustration purposes the components mounted to the top side are represented by box 544 and the components mounted to the bottom side are represented by box 546. In certain embodiments, components mounted to the top side are positioned closer to the connector 510 (see e.g., edge 550 of box 544) and components mounted to the bottom side are set back (see e.g., edge 552) relative to the mounting area for components mounted to the top side so as to fit next to an edge 554 of the printed circuit board 430.

In certain embodiments, the board 530 includes the board edge 554. In certain embodiments, the board edge 554 is one edge of a recess defined by the board 530. In certain embodiments, components mounted to the second side 542 of a double sided peripheral card 520 fits within a recess, one side of which is defined by the cut board edge 554.

In certain embodiments, the low profile connector 510 conforms to a low profile specification. In certain embodiments, the low profile specification includes the PCIe H.2 specification. In certain embodiments, the connector 510 corresponds to the PCIe H2.3 portion of the PCIe specification. When the connector 510 so conforms, it is referred to as an H2.3 connector.

In certain embodiments, the low profile connector 510 is mounted to the board 530 to provide a separation of substantially (i.e., +/−10%) 3.26 mm from the connector datum to the board edge 554. As used herein, a connector datum broadly refers to a card edge insertion stop (i.e., the depth to which a card may be inserted into a connector. By providing such a separation, the gap is sufficient to meet low profile specification tolerances while and M.2 module installation (e.g., a 0.39 mm gap currently). Various aspect of the present disclosure include an appreciation that typical connector, pad size, and pad-to-edge design rules would result in interference with a double-sided module.

Various aspects of the present disclosure include an appreciation that the low profile connector system which includes a specifically configured connector mounting position, a specifically configured connector pad size dimension, a specifically configured pad-to-edge dimension, or a combination thereof, enable use of a double sided module with a single sided connector. Various aspects of the present disclosure include an appreciation that the low profile connector system which includes a specifically configured connector mounting position, a specifically configured connector pad size dimension, a specifically configured pad-to-edge dimension, or a combination thereof, enable heat extraction from both sides of the double sided module of the low profile connector system.

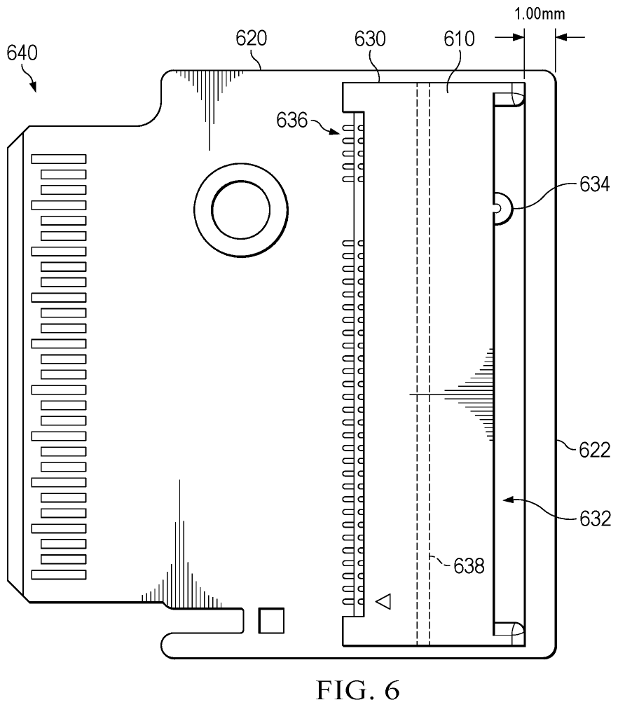

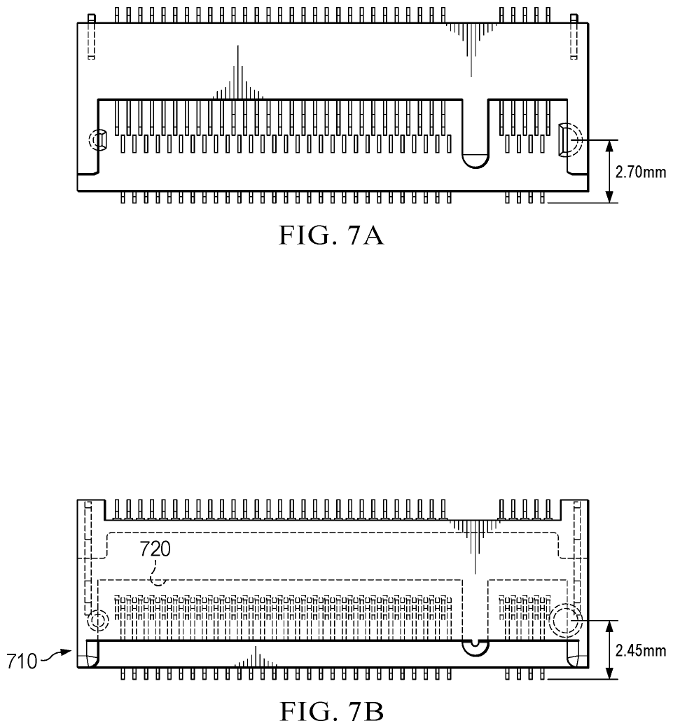

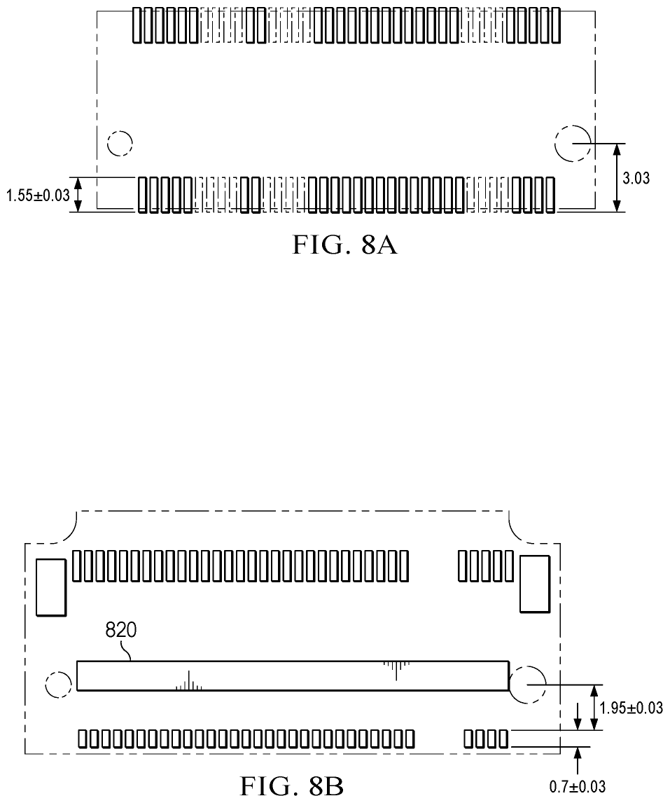

FIG. 6 shows a top view of a portion 600 of a low profile connector system. FIGS. 7A and 7B, generally referred to as FIG. 7, respectively show top views of typical and modified lead portions of a low profile connector. FIGS. 8A and 8B, generally referred to as FIG. 8, respectively show top views of typical and modified pad portions of a low profile connector. In certain embodiments, the low profile connector system conforms to low profile connector system 150.

The low profile connector system includes a low profile connector 610 and a printed circuit board 620 to which the low profile connector 610 is mounted. In certain embodiments, the low profile connector is configured to mount a double sided peripheral card. In certain embodiments, printed circuit board 620 comprises an interposer board, a planar board, or a combination thereof. In certain embodiments, the printed circuit board 620 includes the board edge 622. In certain embodiments, the board edge 622 is one edge of a recess defined by the board 620. In certain embodiments, components mounted to a second side of a double sided peripheral card fit within the recess, one side of which is defined by the cut board edge 622.

In certain embodiments, the low profile connector 610 conforms to a low profile specification. In certain embodiments, the low profile specification includes the PCIe H.2 specification. In certain embodiments, the connector 610 corresponds to the PCIe H2.3 portion of the PCIe specification. When the connector 610 so conforms, it is referred to as an H2.3 connector. In certain embodiments, the low profile connector 610 includes a connector housing 630, a card insertion portion 632, a card insertion key 624, a lead portion 636 for electrically coupling the low profile connector 610 with the printed circuit board 620, a connector datum 638, or a combination thereof. In certain embodiments, the connector housing 630 defines the card insertion portion 632. In certain embodiments, the card insertion portion 632 is positioned along the edge 622 of the printed circuit board 620. In certain embodiments, the connector datum 638 is contained within the connector housing 630. In certain embodiments, the connector datum 638 laterally extends from one interior side of the connector housing 630 to another interior side of the connector housing 630. In certain embodiments, the connector housing 610 is mounted to the printed circuit board 620 at a specifically configured connector mounting portion to allow insertion of a double sided peripheral card into the card insertion portion 632. In certain embodiments, the connector housing 630 is mounted to the printed circuit board 620 such that a distance from the connector datum 638 to the edge 622 of the printed circuit board 630 is optimized to allow insertion of a double sided peripheral card into the card insertion portion. In certain embodiments, the connector housing 610 is mounted to the board 620 to provide a separation of substantially (i.e., +/−10%) 3.26 mm from the connector datum 638 to the board edge 622.

In certain embodiments, the low profile connector 610 is mounted to the board 620 to provide a separation of substantially (i.e., +/−20%) 1.00 mm from the front edge of the connector to the board edge 622. By providing such a separation, the gap is sufficient to meet low profile specification tolerances while a M.2 module is installed (0.39 mm Gap currently). Various aspects of the present disclosure include an appreciation that typical connector, pad size, and pad-to-edge design rules would result in interference with a double-sided module.

In certain embodiments, the low profile connector includes a connector front lead portion which includes leads corresponding to a specifically configured front lead dimension. In certain embodiments, the specifically configured front lead dimension provides shorter front leads 710 when compared with a typical lead length conforming to a low profile connector specification. In certain embodiments, the front leads 710 are positioned in front of a connector datum 720. In certain embodiments, the specifically configured front lead dimension is decreased by substantially (i.e., +/−10%) 0.35 mm when compared with a typical length conforming to a low profile connector specification.

In certain embodiments, the low profile connector includes a connector a pad portion which includes pads corresponding to a specifically configured pad dimension. In certain embodiments, the pads of the pad portion 810 are positioned in front of a connector datum 820. In certain embodiments, the specifically configured pad dimension provides shorter front pads 810 when compared with a typical pad depth conforming to a low profile connector specification. In certain embodiments, the specifically configured pad dimension is decreased by substantially (i.e., +/−10%) 0.21 mm when compared with a typical pad dimension conforming to a low profile connector specification.

In certain embodiments, card edge connectors of double sided modules of a low profile connector system which interface with the connector pads are sized to mate with the pad connectors 810 of the low profile connector.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is Claimed is:

1. A low profile connector for use with a low profile connector system, comprising:
a connector housing, the connector housing defining a card insertion portion, the card insertion portion being positioned along an edge of a printed circuit board;
a connector datum contained within the connector housing, the connector datum extending from one interior side of the connector housing to another interior side of the connector housing; and wherein
the connector housing is mounted to the printed circuit board at a specifically configured connector mounting position to allow insertion of a double sided peripheral card into the card insertion portion.

2. The low profile connector of claim 1, wherein:
the specifically configured connector mounting position is configured such that a distance from the connector datum to an edge of the printed circuit board is optimized to allow insertion of a double sided peripheral card into the card insertion portion.

3. The low profile connector of claim 1, further comprising:
a connector pad portion, the connector pad comprising connector pads corresponding to a specifically configured connector pad size dimension.

4. The low profile connector of claim 1, further comprising:
a connector front lead portion, the connector front lead portion comprising connector front leads corresponding to a specifically configured front lead dimension.

5. The low profile connector of claim 1, wherein:
the low profile connector corresponds to a low profile specification.

6. The low profile connector system of claim 5, wherein:
the low profile specification comprises a PCI Express M.2 low profile specification.

7. A low profile connector system comprising:
a printed circuit board; and,
a low profile connector mounted on the printed circuit board, the low profile connector comprising:
a connector housing, the connector housing defining a card insertion portion, the card insertion portion being positioned along an edge of the printed circuit board;
a connector datum contained within the connector housing, the connector datum extending from one interior side of the connector housing to another interior side of the connector housing; and wherein
the connector housing is mounted to the printed circuit board at a specifically configured connector mounting portion to allow insertion of a double sided peripheral card into the card insertion portion.

8. The low profile connector system of claim 7, wherein:
the specifically configured connector mounting position is configured such that a distance from the connector datum to an edge of the printed circuit board is optimized to allow insertion of a double sided peripheral card into the card insertion portion.

9. The low profile connector system of claim 8, wherein the low profile connector further comprises:
a connector pad portion, the connector pad comprising connector pads corresponding to a specifically configured connector pad size dimension.

10. The low profile connector system of claim 7, wherein the low profile connector further comprises:
a connector front lead portion, the connector front lead portion comprising connector front leads corresponding to a specifically configured front lead dimension.

11. The low profile connector system of claim 7, wherein:
the low profile connector corresponds to a low profile specification.

12. The low profile connector system of claim 11, wherein:
the low profile specification comprises a PCI Express M.2 low profile specification.

13. A system comprising:
a processor;
a data bus coupled to the processor;
a low profile connector system, the low profile connector system comprising:
a printed circuit board; and,
a low profile connector mounted on the printed circuit board, the low profile connector comprising:
a connector housing, the connector housing defining a card insertion portion, the card insertion portion being positioned along an edge of the printed circuit board;
a connector datum contained within the connector housing, the connector datum extending from one interior side of the connector housing to another interior side of the connector housing; and wherein
the connector housing is mounted to the printed circuit board at a specifically configured connector mounting portion to allow insertion of a double sided peripheral card into the card insertion portion.

14. The system of claim 13, wherein:
the specifically configured connector mounting position is configured such that a distance from the connector datum to an edge of the printed circuit board is optimized to allow insertion of a double sided peripheral card into the card insertion portion.

15. The system of claim 13, wherein the low profile connector further comprises:
a connector pad portion, the connector pad comprising connector pads corresponding to a specifically configured connector pad size dimension.

16. The system of claim 13, wherein the low profile connector further comprises:
a connector front lead portion, the connector front lead portion comprising connector front leads corresponding to a specifically configured front lead dimension.

17. The system of claim 13, further comprising:
the low profile connector corresponds to a low profile specification.

18. The system of claim 17, wherein:
the low profile specification comprises a PCI Express M.2 low profile specification.
